(19) United States
(12) Patent Application Publication
(10) Pub. No.: US 2012/0252165 A1
(43) Pub. Date: Oct. 4, 2012

(54) METHOD FOR MANUFACTURING A SEMICONDUCTOR DEVICE

(75) Inventors: Yusuke Nakanoya, Tokyo (JP); Masanori Yoshida, Tokyo (JP); Keiyo Kusanagi, Tokyo (JP)

(73) Assignee: Elpida Memory, Inc.

(21) Appl. No.: 13/430,148

(22) Filed: Mar. 26, 2012

(30) Foreign Application Priority Data
Mar. 31, 2011 (JP) 2011-077738

(51) Int. Cl. H01L 21/56

(52) U.S. Cl. 438/107; 257/E21.502

(57) ABSTRACT

A method for forming a semiconductor device includes the following processes. A first semiconductor chip and a second semiconductor chip are stacked to form a stacked structure. A gap between the first and second semiconductor chips of the stacked structure is filled with a filler. A temperature of the stacked first and second semiconductor chips is kept more than room temperature from the stacking to the filing.

### BACKGROUND OF THE INVENTION

1. Field of the Invention

The present invention generally relates to a method for manufacturing a semiconductor device.

Priority is claimed on Japanese Patent Application No. 2011-077738, filed Mar. 31, 2011, the content of which is incorporated herein by reference.

2. Description of the Related Art

With an increase in the level of integration of semiconductor chips in recent years, there have been accompanying advances, with increasing chip sizes and nanoscaling and multilayer interconnects. In order to achieve higher packaging density, it has become necessary to reduce the package size and thickness.

To accommodate such demands, art regarding MCPs (multichip packages), in which a plurality of semiconductor chips are mounted with high density onto a single interconnect substrate has been developed. Japanese Unexamined Patent Application, First Publication, No. JP-A-2008-294367 discloses a CoC (chip-on-chip) type of semiconductor package (semiconductor device) in which a chip stack of semiconductor chips having through electrodes known as TSVs (through silicon vias) is mounted onto one surface of an interconnect substrate.

When manufacturing a CoC type semiconductor package, a chip stack of a plurality of stacked chips is fabricated. Each of the plurality of semiconductor chips constituting this chip stack includes bump electrodes on first and second surfaces. The plurality of semiconductor chips are brought into opposition, with the first surface of one opposing the second surface of another, and bonds are formed between the bump electrodes provided on the first surface of the one and the bump electrodes provided on the second surface of another, by means of hot-pressing (bump bonding). After fabricating such a chip stack, an underfilling material is filled in between the gaps between each of the stacked semiconductor chips, this underfilling material then being thermally cured, so as to seal the chip stack with the underfilling material.

### SUMMARY

In one embodiment, a method of manufacturing a semiconductor device may include, but is not limited to, the following processes. A first semiconductor chip and a second semiconductor chip are stacked to form a stacked structure. A gap between the first and second semiconductor chips of the stacked structure is filled with a filler. A temperature of the stacked first and second semiconductor chips is kept more than room temperature from the stacking to the filing.

In another embodiment, a method of manufacturing a semiconductor device may include, but is not limited to, the following processes. A plurality of semiconductor chips are electrically coupled to each other. A temperature of the plurality of semiconductor chips is kept more than room temperature during and after electrically coupling the plurality of semiconductor chips to each other. Gaps between the plurality of semiconductor chips are filled with a filler while heating the plurality of semiconductor chips immediately after the keeping.

In still another embodiment, a method for forming a semiconductor device may include, but is not limited to, the following processes. A stacked structure including first and second substrates stacked with one another is formed. A gap between the first and second substrates is filled with an underfilling material while keeping a temperature of the stacked structure higher than a room temperature from the forming to the filling.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view illustrating the semiconductor device in accordance with a first preferred embodiment of the present invention;

FIG. 2A is a fragmentary cross sectional elevation view illustrating the semiconductor device in a step involved in a method of forming the semiconductor device of FIG. 1 in accordance with the first preferred embodiment of the present invention;

FIG. 2B is a fragmentary cross sectional elevation view illustrating the semiconductor device in a step, subsequent to FIG. 2A, involved in the method of forming the semiconductor device of FIG. 1 in accordance with the first preferred embodiment of the present invention;

FIG. 2C is a fragmentary cross sectional elevation view illustrating the semiconductor device in a step, subsequent to FIG. 2B, involved in the method of forming the semiconductor device of FIG. 1 in accordance with the first preferred embodiment of the present invention;

FIG. 3 is a fragmentary cross sectional elevation view illustrating the semiconductor device in a step, subsequent to FIG. 2C, involved in the method of forming the semiconductor device of FIG. 1 in accordance with the first preferred embodiment of the present invention;

FIG. 4A is a fragmentary cross sectional elevation view illustrating the semiconductor device in a step, subsequent to FIG. 3, involved in the method of forming the semiconductor device of FIG. 1 in accordance with the first preferred embodiment of the present invention;

FIG. 4B is a fragmentary cross sectional elevation view illustrating the semiconductor device in a step, subsequent to FIG. 4A, involved in the method of forming the semiconductor device of FIG. 1 in accordance with the first preferred embodiment of the present invention;

FIG. 4C is a fragmentary cross sectional elevation view illustrating the semiconductor device that is sealed by the under filling material in accordance with the first preferred embodiment of the present invention;

FIG. 5 is a fragmentary cross sectional elevation view illustrating a wiring board in accordance with the first preferred embodiment of the present invention;

FIG. 6A is a fragmentary cross sectional elevation view illustrating the semiconductor device in a step, subsequent to FIG. 4B, involved in the method of forming the semiconductor device of FIG. 1 in accordance with the first preferred embodiment of the present invention;

FIG. 6B is a fragmentary cross sectional elevation view illustrating the semiconductor device in a step, subsequent to FIG. 6A, involved in the method of forming the semiconductor device of FIG. 1 in accordance with the first preferred embodiment of the present invention;

FIG. 6C is a fragmentary cross sectional elevation view illustrating the semiconductor device in a step, subsequent to FIG. 6B, involved in the method of forming the semiconductor device of FIG. 1 in accordance with the first preferred embodiment of the present invention;

FIG. 7 is a fragmentary cross sectional elevation view illustrating the semiconductor device in a step, subsequent to FIG. 6C, involved in the method of forming the semiconductor device of FIG. 1 in accordance with the first preferred embodiment of the present invention;

FIG. 8 is a fragmentary cross sectional elevation view illustrating the semiconductor device in a step, subsequent to FIG. 7, involved in the method of forming the semiconductor device of FIG. 1 in accordance with the first preferred embodiment of the present invention;

FIG. 9 is a fragmentary cross sectional elevation view illustrating the semiconductor device in a step, subsequent to FIG. 8, involved in the method of forming the semiconductor device of FIG. 1 in accordance with the first preferred embodiment of the present invention;

FIG. 10 is a fragmentary cross sectional elevation view illustrating the batch-fabricated semiconductor device in accordance with the first preferred embodiment of the present invention;

FIG. 11 is a fragmentary cross sectional elevation view illustrating a semiconductor device in accordance with a second preferred embodiment of the present invention;

FIG. 12A is a fragmentary cross sectional elevation view illustrating the semiconductor device in a step involved in a method of forming the semiconductor device of FIG. 11 in accordance with the second preferred embodiment of the present invention;

FIG. 12B is a fragmentary cross sectional elevation view illustrating the semiconductor device in a step, subsequent to FIG. 12A, involved in the method of forming the semiconductor device of FIG. 11 in accordance with the second preferred embodiment of the present invention;

FIG. 12C is a fragmentary cross sectional elevation view illustrating the semiconductor device in a step, subsequent to FIG. 12B, involved in the method of forming the semiconductor device of FIG. 11 in accordance with the second preferred embodiment of the present invention;

FIG. 13 is a fragmentary cross sectional elevation view illustrating the semiconductor device in a step, subsequent to FIG. 12C, involved in the method of forming the semiconductor device of FIG. 11 in accordance with the second preferred embodiment of the present invention;

FIG. 14A is a fragmentary cross sectional elevation view illustrating the semiconductor device in a step, subsequent to FIG. 13, involved in the method of forming the semiconductor device of FIG. 11 in accordance with the second preferred embodiment of the present invention;

FIG. 14B is a fragmentary cross sectional elevation view illustrating the semiconductor device in a step, subsequent to FIG. 14A, involved in the method of forming the semiconductor device of FIG. 11 in accordance with the second preferred embodiment of the present invention;

FIG. 15 is a fragmentary cross sectional elevation view illustrating the semiconductor device in a step, subsequent to FIG. 14B, involved in the method of forming the semiconductor device of FIG. 11 in accordance with the second preferred embodiment of the present invention;

FIG. 16 is a fragmentary cross sectional elevation view illustrating the semiconductor device that is sealed by the under filling material in accordance with the second preferred embodiment of the present invention;

FIG. 17 is a fragmentary cross sectional elevation view illustrating a wiring board in accordance with the second preferred embodiment of the present invention;

FIG. 18A is a fragmentary cross sectional elevation view illustrating the semiconductor device in a step, subsequent to FIG. 15, involved in the method of forming the semiconductor device of FIG. 11 in accordance with the second preferred embodiment of the present invention;

FIG. 18B is a fragmentary cross sectional elevation view illustrating the semiconductor device in a step, subsequent to FIG. 18A, involved in the method of forming the semiconductor device of FIG. 11 in accordance with the second preferred embodiment of the present invention;

FIG. 18C is a fragmentary cross sectional elevation view illustrating the semiconductor device in a step, subsequent to FIG. 18B, involved in the method of forming the semiconductor device of FIG. 11 in accordance with the second preferred embodiment of the present invention;

FIG. 19 is a fragmentary cross sectional elevation view illustrating the semiconductor device in a step, subsequent to FIG. 18C, involved in the method of forming the semiconductor device of FIG. 11 in accordance with the second preferred embodiment of the present invention;

FIG. 20 is a fragmentary cross sectional elevation view illustrating the semiconductor device in a step, subsequent to FIG. 19, involved in the method of forming the semiconductor device of FIG. 11 in accordance with the second preferred embodiment of the present invention;

FIG. 21 is a fragmentary cross sectional elevation view illustrating the semiconductor device in a step, subsequent to FIG. 20, involved in the method of forming the semiconductor device of FIG. 11 in accordance with the second preferred embodiment of the present invention;

FIG. 22 is a fragmentary cross sectional elevation view illustrating the batch-fabricated semiconductor device in accordance with the second preferred embodiment of the present invention;

FIG. 23A is a fragmentary cross sectional elevation view illustrating the semiconductor device in a step involved in a method of forming the semiconductor device of FIG. 1 in accordance with a third preferred embodiment of the present invention;

FIG. 23B is a fragmentary cross sectional elevation view illustrating the semiconductor device in a step, subsequent to FIG. 23A, involved in the method of forming the semiconductor device of FIG. 1 in accordance with the third preferred embodiment of the present invention;

FIG. 23C is a fragmentary cross sectional elevation view illustrating the semiconductor device in a step, subsequent to FIG. 23B, involved in the method of forming the semiconductor device of FIG. 1 in accordance with the third preferred embodiment of the present invention; and

FIG. 23D is a fragmentary cross sectional elevation view illustrating the semiconductor device in a step, subsequent to FIG. 23C, involved in the method of forming the semiconductor device of FIG. 1 in accordance with the third preferred embodiment of the present invention.

### DETAILED DESCRIPTION OF THE PREFERRED EMBODIMENTS

Before describing the present invention, the related art will be explained, in order to facilitate the understanding of the present invention.

Because the above-described chip stack is constituted by a plurality of stacked semiconductor chips, it tends to become thick and, to achieve overall thinness, it is necessary to reduce the thickness of each of the semiconductor chips. However, when the thickness of each of the semiconductor chips is reduced, when thermally curing the above-described underfilling material, curing shrinkage and internal stress caused by thermal expansion and the like of the underfilling material is imparted to the chip stack.

In this case, deformation such as warping occurs to the semiconductor chips, and because of the stress imparted to the bump electrode bonds (bump bonds), breakage of these bump bonds and cracking of the semiconductor chips occurred.

Specifically, Japanese Unexamined Patent Application, First Publication, No. JP-A-2008-294367 discloses the heating of a thin semiconductor chip having through electrodes to the melting temperature of solder and forming bonds between the corresponding through electrodes via the bumps that are heated to melting, after which cooling is done to a room temperature. However, because the semiconductor chips are thin, with a thickness of, for example, approximately 50 μm, in the case of stacking semiconductor chips of different sizes or semiconductor chips having different circuits, each exhibits a different warping behavior during the cooling, after bonding, from the high temperature at the time of bonding to the room temperature. In this case, stress is imparted to the bump bonds between the different types of semiconductor chips, this causing breakage of the bump bonds.

Given this, Japanese Unexamined Patent Application, First Publication, No. JP-A-2008-294367 proposes the provision of a reinforcing chip with a thickness that is greater than that of the semiconductor chips to increase the rigidity of the chip stack, thereby suppressing breakage of the bumps caused by stress concentrations. Even if such a reinforcing chip is added, however, because the warping behavior is different between chips of different types, stress is imparted to the bump bonds.

Also, even in the case in which different type chips of the same size are stacked, because different circuits and interconnects are formed on the surfaces thereof, there is a difference in the warping behavior between chips of different types. In this case as well, stress is therefore imparted to the bump bonds between the chips of different types, this causing breakage of the bump bonds.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method of manufacturing a semiconductor device may include, but is not limited to, the following processes. A first semiconductor chip and a second semiconductor chip are stacked to form a stacked structure. A gap between the first and second semiconductor chips of the stacked structure is filled with a filler. A temperature of the stacked first and second semiconductor chips is kept more than room temperature from the stacking to the filing.

In some cases, keeping the temperature of the stacked structure may include, but is not limited to, housing the stacked structure in a heat-insulating tray.

In some cases, keeping the temperature of the stacked structure may include, but is not limited to, keeping the temperature of the stacked structure in a range of 80° C. to 100° C.

In some cases, the method may further include, but is not limited to, forming a passivation film over the first semiconductor chip and the second semiconductor chip before stacking the first semiconductor chip and the second semiconductor chip.

In some cases, stacking the first semiconductor chip and the second semiconductor chip may include, but is not limited to, heating the first semiconductor chip and the second semiconductor chip while applying a load to the first semiconductor chip and the second semiconductor chip.

In some cases, the method may further include, but is not limited to, hardening the filler by heating the first semiconductor chip and the second semiconductor chip.

In some cases, the method may further include, but is not limited to, stacking the stacked structure on a wiring board; and sealing the stacked structure and the wiring board with a resin.

In some cases, filing the gap may include, but is not limited to, heating the stacked structure while the gap between the first and second semiconductor chips is filled with the filler.

In another embodiment, a method of manufacturing a semiconductor device may include, but is not limited to, the following processes. A plurality of semiconductor chips are electrically coupled to each other. A temperature of the plurality of semiconductor chips is kept more than room temperature during and after electrically coupling the plurality of semiconductor chips to each other. Gaps between the plurality of semiconductor chips are filled with a filler while heating the plurality of semiconductor chips immediately after the keeping.

In some cases, keeping the temperature of the plurality of semiconductor chips may include, but is not limited to, housing the plurality of semiconductor chips in a heat-insulating tray.

In some cases, keeping the temperature of the plurality of semiconductor chips may include, but is not limited to, keeping the temperature of the plurality of semiconductor chips in a range of 80° C. to 100° C.

In some cases, the method may further include, but is not limited to, forming a passivation film over the plurality of semiconductor chips before electrically coupling the plurality of semiconductor chips.

In some cases, electrically coupling the plurality of semiconductor chips to each other may include, but is not limited to, heating the plurality of semiconductor chips while applying a load to the plurality of semiconductor chips.

In some cases, the method may further include, but is not limited to, hardening the filler by heating the plurality of semiconductor chips.

In some cases, the method may further include, but is not limited to, stacking the plurality of semiconductor chips on a wiring board; and sealing the plurality of semiconductor chips and the wiring board with a resin.

In still another embodiment, a method for forming a semiconductor device may include, but is not limited to, the following processes. A stacked structure including first and second substrates stacked with one another is formed. A gap between the first and second substrates is filled with an underfilling material while keeping a temperature of the stacked structure higher than a room temperature from the forming to the filling.

In some cases, forming the stacked structure may include, but is not limited to, each of the first and second substrates being a semiconductor chip.

In some cases, forming the stacked structure may include, but is not limited to, the second substrate having a size that is different from the first substrate.

In some cases, keeping the temperature of the stacked structure may include, but is not limited to, keeping the temperature of the stacked structure in a range of 80° C. to 100° C.

In some cases, the method may further include, but is not limited to, mounting the stacked structure on a wiring board; and forming a sealing resin on the wiring board to cover the stacked structure.

Hereinafter, a method for forming a semiconductor device according to an embodiment of the invention will be described in detail with reference to the drawings. As a convenience in aiding an understanding of the features, the drawings used in the following descriptions sometimes show characteristic parts enlarged, and the dimensional proportions of various constituent elements are not necessarily the same as in actuality. Also, the materials, dimension and the like in the following descriptions are exemplary, the present embodiment not necessarily being restricted thereto. The present embodiment may be embodied by various changes, within the scope of the essence thereof.

### First Embodiment

### Semiconductor Device

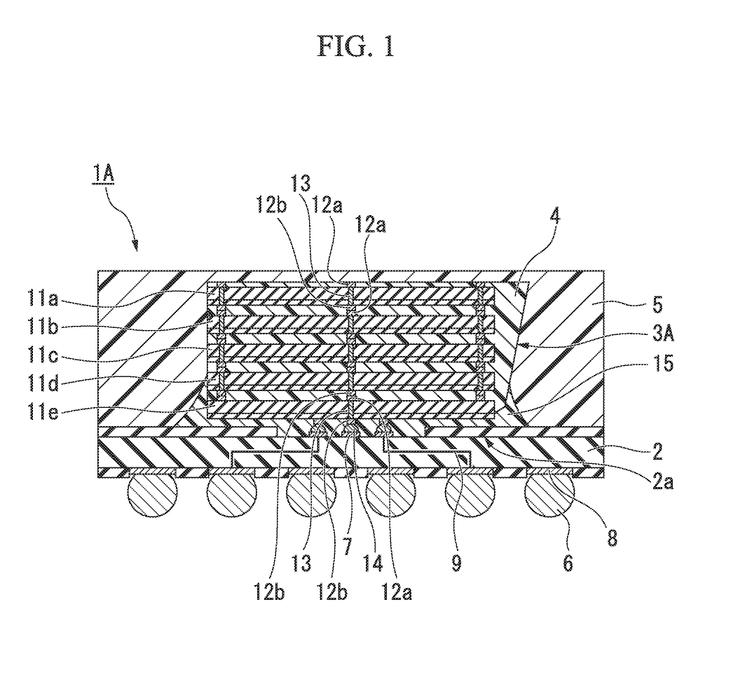

First, a CoC type semiconductor package 1A shown in FIG. 1 will be described as a first embodiment.

The semiconductor package 1A, as shown in FIG. 1, may include, but is not limited to, an interconnect substrate 2, a chip stack 3A, an underfilling material (filler, first sealing element) 4, a molding resin (second sealing element) 5, and a plurality of solder balls (external connection terminals) 6. The chip stack 3A is mounted to one surface (upper surface) of the interconnect substrate 2. The underfilling material 4 covers the chip stack 3A. The molding resin 5 covers the underfilling material 4. The plurality of solder balls 6 are disposed on the other surface (lower surface) of the interconnect substrate 2. By this configuration, the semiconductor package 1A has a package structure known as a BGA (ball grid array).

The interconnect substrate 2 is made of a printed circuit board having a rectangular plan-view shape. This printed circuit board may be, but is not limited to, an insulating substrate on which a conductive pattern or the like made of a conductive material such as copper is formed. The conductive pattern is covered with an insulating material such as solder resist. The insulating substrate may include, but is not limited to, fiberglass epoxy resin.

In this example, an interconnect substrate 2 having a thickness of approximately 0.2 mm is used.

In the center part of the upper surface of the interconnect substrate 2, a mounting area 2a is provided onto which a chip stack 3A is mounted. A plurality of pad electrodes (third connection terminals) 7 are arranged in the mounting area 2a of the interconnect substrate 2. On the other surface (lower surface) of the interconnect substrate 2 are arranged a plurality of connection lands 8. The solder balls 6 are disposed over these connection lands 8. A lead interconnect part 9 (shown schematically in FIG. 1) with vias and interconnect patterns and the like for electrical connection between the pad electrodes 7 and the connection lands 8 is provided on the interconnect substrate 2. With the exception of the parts in which the above-described pad electrodes 7 and connection lands 8 are formed, the surface of the interconnect substrate 2 is covered with an insulating film (not shown).

The chip stack 3A may include, but is not limited to, a plurality of (five in this example) stacked semiconductor chips 11a to 11e, these being, in sequence from the side opposite the interconnect substrate 2 (the uppermost side), a plurality (in this example, four) of memory chips (first semiconductor chips) 11a to 11d and an interface chip (second semiconductor chip) 11e are formed. Each of the plurality (in this example, four) of memory chips (first semiconductor chips) 11a to 11d may include, but is not limited to, DRAM (dynamic random-access memory) circuits. The interface chip (second semiconductor chip) 11e may include, but is not limited to, interface circuits for interfacing between each of the memory chips 11a to 11d and the interconnect substrate 2. In this example, semiconductor chips 11a to 11e having a thickness of approximately 50 μm are used.

The plurality of memory chips 11a to 11d have a rectangular shape when seen in plan view. The plurality of memory chips 11a to 11d have a shape that is smaller than that of the interconnect substrate 2. Each of the memory chips 11a to 11d may include, but is not limited to, a plurality of first bump electrodes (first connection terminals) 12a on one surface side thereof. Each of the memory chips 11a to 11d may include, but is not limited to, a plurality of second bump electrodes (second connection terminals) 12b on the other surface side thereof. Each of the memory chips 11a to 11d may include, but is not limited to, a plurality of through electrodes (TSVs) 13 making connections between the first bump electrodes 12a and the second bump electrodes 12b. The plurality of memory chips 11a to 11d are stacked, with the one surface and the other surfaces thereof brought into opposition, the first bump electrodes 12a and the second bump electrodes 12b therebetween being bonded.

The interface chip 11e has a rectangular shape viewed in plan view. The interface chip 11e is substantially the same size as the above-noted memory chips 11a to 11d. The interface chip 11e may include, but is not limited to, a plurality of first bump electrodes (first connection terminals) 12a on one surface side thereof. The interface chip 11e may include, but is not limited to, a plurality of second bump electrodes (second connection terminals) 12b on the other surface side thereof. The interface chip 11e may include, but is not limited to, a plurality of through electrodes (TSVs) 13 making connections between the first bump electrodes 12a and the second bump electrodes 12b. The interface chip 11e is stacked with the one surface thereof and the other surface of the memory chip 11d brought into opposition, the first bump electrodes 12a and the second bump electrodes 12b therebetween being bonded.

With the interface chip 11e of the chip stack 3A positioned at the uppermost layer facing downward and the other surface of the interface chip 11e being brought into opposition with one surface (mounting area 2a) of the interconnect substrate 2, the second bump electrodes 12b and the pad electrodes 7 therebetween are bonded, via wire bumps (bonding members) 14. Additionally the chip stack 3A is adhered and held to the mounting area 2a of the interconnect substrate 2, via an insulating adhesive member 15 that fills between the one surface of the interconnect substrate 2 and the other surface of the interface chip 11e.

The above-noted interface chip 11e may include, but is not limited to, on both sides of the through electrodes 13 in the center part thereof, a plurality of second bump electrodes 12b in an alternately spaced arrangement. The plurality of second bump electrodes 12b are aligned with the pitch of the pad electrodes 7 of the above-noted interconnect substrate 2. Between the second bump electrodes 12b on both sides of the through electrodes 13 and the through electrodes 13 is provided an interconnect pattern (not shown) for the purpose of reconnection, thereby adjusting the pitch with the pad electrodes 7 of the interconnect substrate 2.

In the plurality of memory chips 11a to 11d, with respect to the plurality of through electrodes 13 arranged in the center part thereof, a plurality of through electrodes 13 on both sides interposing the center part constitute dummy electrodes so as to reinforce connection. These dummy electrodes, therefore, need not be electrically connected to the interface chip 11e. These dummy electrodes are constituted so as to be connected to dummy bump electrodes 12a arranged on both sides interposing the center part of the interface chip 11e.

The underfilling material 4, as a first sealing element, is thermally cured, so as to seal the chip stack 3A after filling in each of the gap between the plurality of semiconductor chips 11a to 11e constituting the chip stack 3A.

The molding resin 5, as a second sealing element, provides overall sealing of the entire one surface side of the interconnect substrate 2, in a condition in that covers the entire chip stack 3A that was sealed by the underfilling material 4.

### (Method for Forming a Semiconductor Device)

The processes for forming the semiconductor package 1A shown in FIG. 1 will be described.

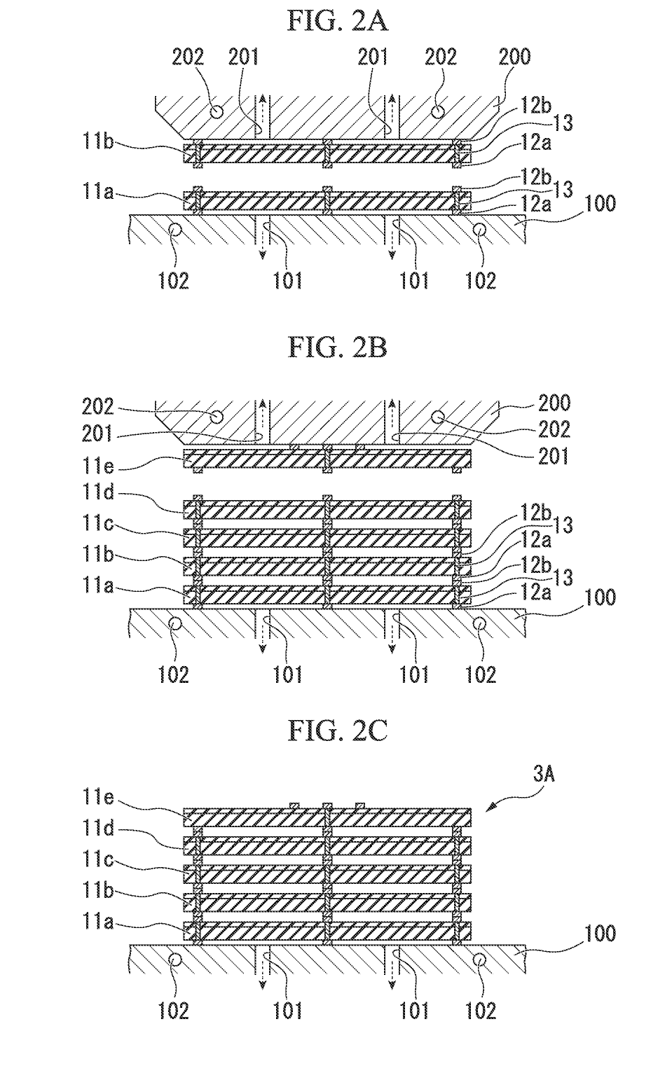

When forming the semiconductor package 1A, first, as shown in FIG. 2A to FIG. 2C, the chip stack 3A that is the stacking of the above-noted plurality of semiconductor chips 11a to 11e is formed.

As shown in FIG. 2A, the first-layer memory chip 11a is placed onto a vacuum chucking stage 100, with the surface thereof (one surface) having formed thereon a plurality of first bump electrodes 12a facing downward. The memory chip 11a is then vacuum chucked by a plurality of vacuum suction holes 101 provided on the vacuum chucking stage 100, thereby holding it onto the vacuum chucking stage 100.

The vacuum chucking stage 100 is also provided with a heater (heating means) 102 for the purpose of heating the vacuum chucking stage 100. The heater 102 can heat the vacuum chucking stage 100 by causing a heated working fluid to flow through a tube path provided within the vacuum chucking stage 100.

From this condition, using a bonding tool 200 the second-layer memory chip 11b is stack-mounted (flip-chip mounted) onto the first-layer memory chip 11a. In this flip-chip mounting, while vacuum suction holes 201 provided in the bonding tool 200 vacuum chuck the second-layer memory chip 11b, the bonding tool 200 holds the memory chip 11b with the surface (one surface) on which the first bump electrodes 12a are formed facing downward.

The bonding tool 200 also is provided with a heater (heating means) 202 for the purpose of heating the bonding tool 200. The heater 202 can heat the bonding tool 200 by causing a heated working fluid to flow through a tube path provided within the bonding tool 200.

The bonding tool 200, as shown in FIG. 2B, brings one surface of the second-layer memory chip 11b and the other surface of the first-layer memory chip 11a therebeneath into opposition. The bonding tool 200 places the second-layer memory chip 11b on to the first-layer memory 11a, with the positions of the first bump electrodes 12a and the second bump electrodes 12b therebetween aligned. In this condition, the bonding tool applies a load as it heats at a high temperature (for example, approximately 300° C.) so as to bond (flip-chip bond) the first bump electrodes 12a and the second bump electrodes 12b by hot-pressing. When this bonding is done, ultrasonic waves may be applied in addition to a load.

By doing this, an electrical connection (flip-chip connection) is made between the first bump electrodes 12a and the second bump electrodes 12b. The second-layer memory chip 11b is flip-chip mounted on top of the first-layer memory chip 11a.

From this condition, using the same method as in the case of flip-chip mounting the second-layer memory chip 11b onto the first-layer memory chip 11a as described above, the third-layer memory chip 11c is mounted to the second-layer memory chip 11b, the fourth-layer memory chip 11d is mounted to the third-layer memory chip 11c, and the fifth-layer interface chip 11e is mounted to the fourth-layer memory chip 11d, by successive flip-chip mounting. By doing this, the chip stack 3A as shown in FIG. 2C, with the plurality of stacked semiconductor chips 11a to 11e is obtained.

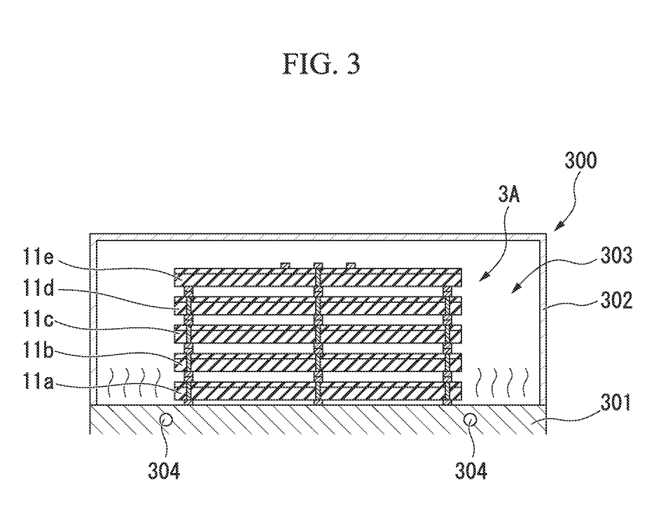

Then, in the condition as shown in FIG. 3, in which it is housed in a heat-insulating tray 300, the chip stack 3A is warmed so that the temperature thereof does not drop to a room temperature and transported to the next process step. That is, the temperature of the chip stack 3A is kept warmed more than the room temperature. In this case, it is possible to suppress the warping behavior of the plurality of semiconductor chips 11a to 11e in the heated chip stack 3A caused by temperature change.

Specifically, a passivation film (polyimide) is generally formed on the surfaces of the semiconductor chips 11a to 11e, and in the thin semiconductor chips 11a to 11e, the passivation film causes concave warping. In a chip stack 3A that is warmed to approximately 80° C. to 100° C., because the passivation film undergoes thermal expansion, it is possible to reduce the warping of the semiconductor chips 11a to 11e.

The heat-insulating tray 300 has a tray body 301, a cover 302 mounted to the tray body 301 so as to be freely openable and closable. The heat-insulating tray 300 forms a housing space 303 that houses the chip stack 3A within the cover 302. The heat-insulating tray 300 can, by a heater 304 provided inside the tray body 301, warm the chip stack 3A to a prescribed temperature, while adjusting the temperature within the housing space 303. The heat-insulating tray 300 is not necessarily restricted to the constitution shown in FIG. 3, and it is sufficient that it be capable of applying a temperature to the chip stack 3A until the chip stack 3A is transported to the next process, and the constitution thereof can be changed as appropriate.

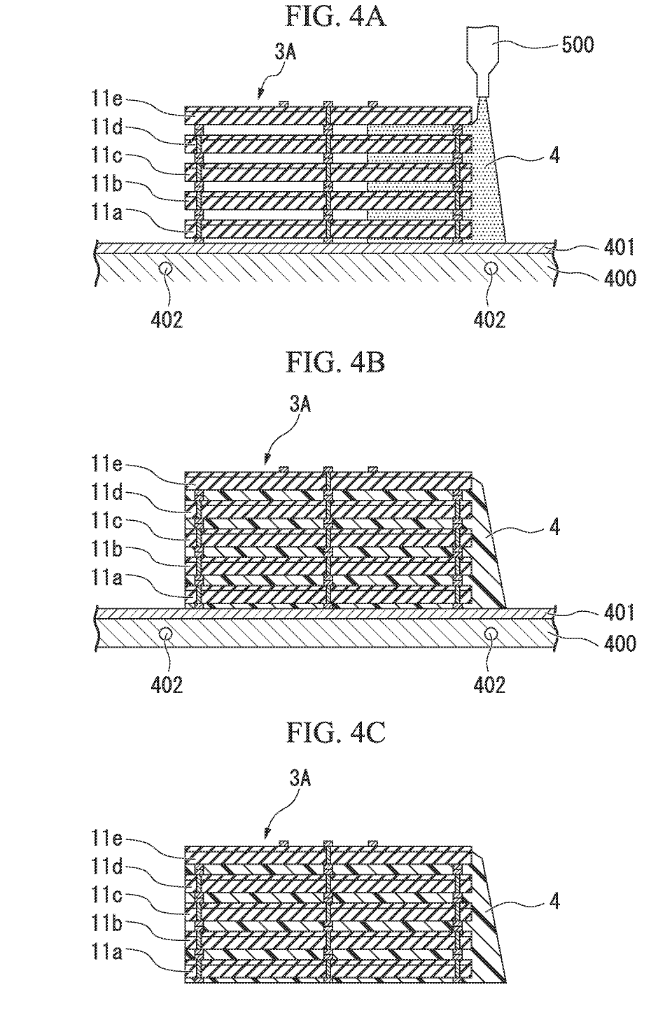

As shown in FIG. 4A to 4C, the underfilling material 4 is filled into each of the gaps of the chip stack 3, which has been warmed to a prescribed temperature (for example, approximately 80° C. to 100° C.), thereby sealing the chip stack 3.

As shown in FIG. 4A, the chip stack 3A is placed onto a coating stage 400. A coating sheet 401 is attached on a surface on the coating stage 400. The coating sheet 401 is made from a material having poor wetting with the underfilling material 4, such as a fluoride-based sheet or a sheet to which a silicone-based adhesive is applied. The coating stage 400 is provided with a heater (heating means) 402 for the purpose of heating the coating stage 400. The heater 402 can heat the coating stage 400 by causing a heated working fluid to flow through a tube path provided within the coating stage 400.

From this condition, using a dispenser 500 that supplies the liquefied underfilling material 4, the underfilling material 4 is coated from the vicinity of an edge part at a position that is along one side of the chip stack 3A in the direction of each of the gaps in the chip stack 3A. When this is done, the underfilling material 4 is filled into the gaps of the chip stack 3A by capillary action as it seeps into the gaps.

When this is done, because the underfilling material 4 is filled into the chip stack 3A that is in a warmed condition, the flowability of the underfilling material 4 is improved. Also, it is possible to achieve good filling of the underfilling material 4 into each gap in the chip stack 3A, and to reduce the occurrence of voids and the like.

Because the underfilling material 4 that oozes outward into the surrounding area from each of the gaps in the chip stack 3A is prevented from spreading over the surface by the coating sheet 401, which has poor wetting with the underfilling material 4, although there is a gradually spreading going from the uppermost toward the lowermost layer side in the width direction, it is possible to reduce the width thereof.

From this condition, as shown in FIG. 4B, by heating (curing) the underfilling material 4 at, for example, approximately 125° C., the underfilling material 4 hardens. By doing this, a chip stack 3A that is sealed by the underfilling material 4 is formed.

In the chip stack 3A that is sealed by the underfilling material 4, when lowering the temperature to a room temperature after curing of the underfilling material 4, it is possible for the cured underfilling material 4 to suppress the warping behavior of each of the semiconductor chips 11a to 11e.

As shown in FIG. 4C, the chip stack 3A that is sealed by the underfilling material 4 is peeled away from the coating sheet 401. When this is done, the chip stack 3A that is sealed by the underfilling material 4 can be easily peeled away from the coating sheet 401, which has poor wetting with the underfilling material 4. The chip stack 3A that is sealed by the underfilling material 4 is then housed in a housing tray (not shown) and transported to the next process step.

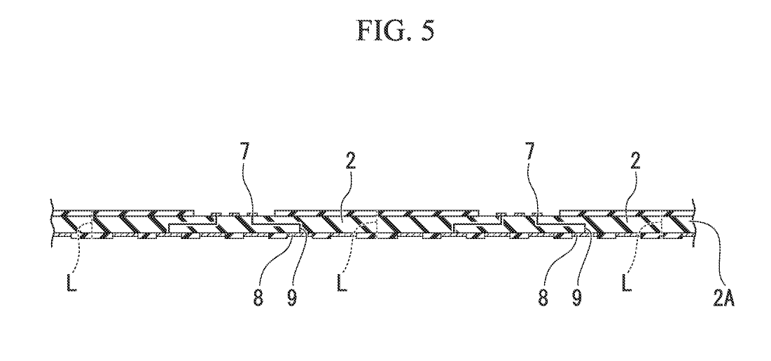

As shown in FIG. 5, a wiring board 2A with an arrangement of a plurality of parts that become the interconnect substrates 2 is prepared. This interconnect wiring board 2A may be, but is not limited to, a fiberglass epoxy resin board, having a plurality of parts that become the interconnect substrates 2 arranged in matrix fashion. By finally dicing the parts that will become the interconnect substrates 2 along the dicing line L, the wiring board 2A can be cut away into individual interconnect substrates 2.

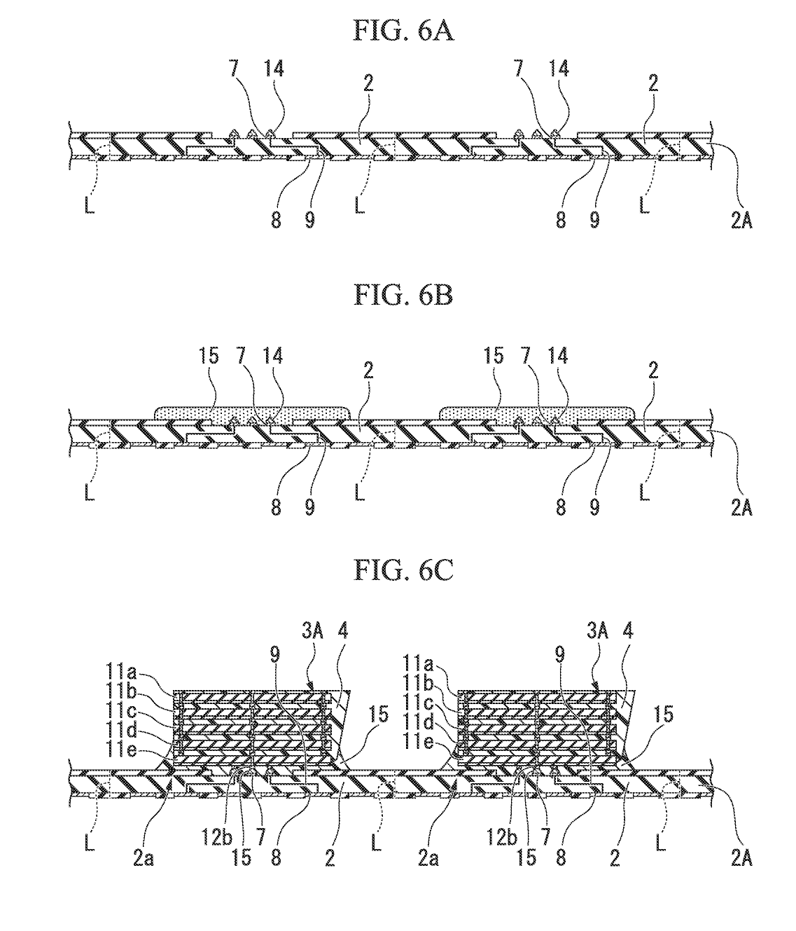

As shown in FIG. 6A to 6C, the chip stacks 3A that are sealed by the underfilling material 4 are mounted on one surface of this interconnect wiring board 2A for each of the parts that will become the interconnect substrates 2.

As shown in FIG. 6A, a wire bump 14 is disposed over each pad electrode 7 in the parts that become the interconnect substrate 2. The wire bumps 14 are formed, for example, by using a wire bonding apparatus (not shown) as follows. Wires made of gold, copper, or the like having melted balls at the ends thereof are bonded onto the pad electrodes 7 using heat, pressure and ultrasonic energy. Then, the rear ends of the wires are pulled to cut them.

As shown in FIG. 6B, a dispenser (not shown) that supplies a liquefied adhesive member 15 known as NCP (non-conductive paste) is used to apply the adhesive member 15 to each of the mounting areas 2a of parts that become the interconnect substrates 2 of the wiring board 2A.

As shown in FIG. 6C, a bonding tool (not shown) is used to flip-chip mount the chip stacks 3A to the mounting areas 2a of the parts that become the interconnect substrates 2 of the wiring board 2A.

In this flip-chip mounting, the chip stack 3A is vacuum chucked by the vacuum suction holes of the bonding tool, as the chip stack 3A is held by the bonding tool, with the interface chip 11e facing downward.

The bonding tool brings one surface of the interface chip 11e into opposition with the mounting area 2a of the part that becomes the interconnect substrate 2 and, with the positions of the first bump electrodes 12a and the pad electrodes 7 therebeteween aligned. In this condition, the bonding tool places the chip stack 3A, which is sealed by the underfilling material 4, onto the mounting area 2a of the part that will become the interconnect substrate 2. By the bonding tool heating to a high temperature (for example, approximately 300° C.) while applying a load, the second bump electrodes 12b and the pad electrodes 7 are thermally bonded (flip-chip bonded) via the wire bumps 14. When this bonding is done, ultrasonic waves may be applied in addition to a load.

By doing this, an electrical connection (flip-chip connection) is made between the second bump electrodes 12b and the pad electrodes 7 via the wire bumps 14. The chip stacks 3A that are sealed by the underfilling material 4 are flip-chip mounted to the mounting areas 2a of the part that becomes the interconnect substrates 2 of the wiring board 2A.

The adhesive member 15 is cured in the condition in which it seeps out from between the one surface of the wiring board 2A and the one surface of the interface chip 11e. By doing this, the chip stack 3A that is sealed by the underfilling material 4 is adhered and held, via the adhesive member 15, to the mounting area 2a of the part that becomes the interconnect substrate 2 of the wiring board 2A. The operation that uses this type of bonding tool is repeated for each part that becomes an interconnect substrate 2 of the wiring board 2A.

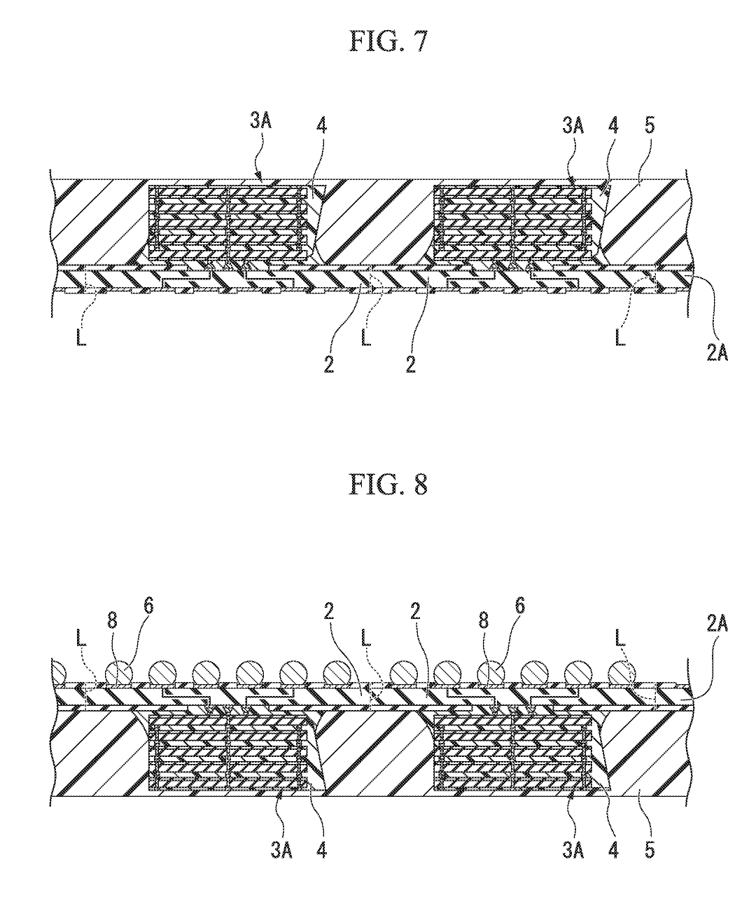

As shown in FIG. 7, one side of the wiring board 2A is sealed with the molding resin 5, so as to cover the chip stacks 3A that are sealed by the underfilling material 4. For example, a transfer molding apparatus (not shown) is used. This transfer molding apparatus has a pair of molds, constituted by a lower mold (fixed mold) and an upper mold (moving mold). The lower mold holds the other surface side of the wiring board 2A. The upper mold forms a cavity space into which the molding resin 5 is filled. The upper mold is in opposition to the one surface side of the wiring board 2A. The upper mold moves relatively to join or to separate freely with respect to the lower mold.

Then, the wiring board 2A onto which the chip stack 3A that is sealed with the underfilling material 4 is mounted is set into the transfer molding apparatus mold. The molding resin 5 that has been heated to melting is injected into the cavity space within the mold. The molding resin 5 may be, but is not limited to, a thermally cured resin such as an epoxy resin.

In this condition, by heating (curing) the molding resin 5 at a prescribed temperature (for example, approximately 180° C.) the molding resin 5 hardens. By additionally baking at a prescribed temperature, the molding resin 5 is completely hardened. By doing this, the one surface side of the wiring board 2A is completely sealed by the molding resin 5.

As shown in FIG. 8, the solder balls 6 are placed onto the connection lands 8 that are provided on the parts that become the interconnect substrates 2 of the wiring board 2A. For example, a mounting tool (not shown) of a ball mounter in which a plurality of vacuum suction holes are formed is used to vacuum chuck a plurality of solder balls 6. The mounting tool transfers and forms flux onto the plurality of solder balls 6, after which solder balls 6 are placed on the connection lands 8 of each part that will become the interconnect substrates 2 of the wiring board 2A. Then, after placing solder balls 6 on all of the parts that will become the interconnect substrates 2 of the wiring board 2A, reflowing is performed to the wiring board 2A. By doing this, the solder balls 6 are disposed over the connection lands 8 of the parts that will become the interconnect substrates 2 of the wiring board 2A.

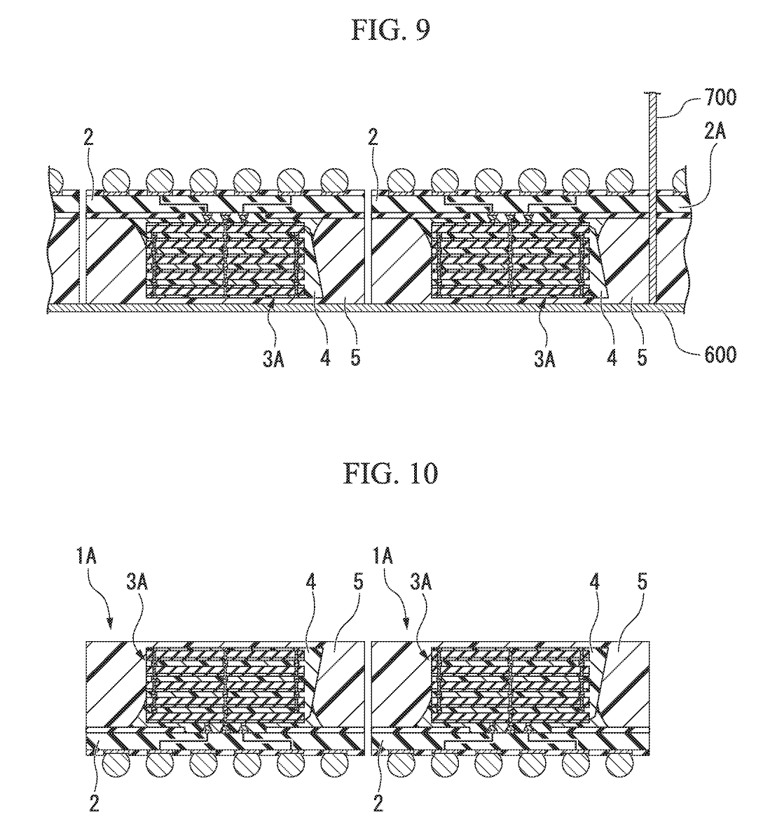

As shown in FIG. 9, by dicing the wiring board 2A into the parts that will become the interconnect substrates 2, separation is done into the individual semiconductor packages 1A. For example, a dicing tape 600 is attached to the molding resin 5 side of the wiring board 2A. Then, a dicing blade 700 is used to dice the wiring board 2A along the dicing line L, from the side opposite the side with the dicing tape 600. By doing this, separation is done into the individual semiconductor packages 1A. Then, by peeling these semiconductor packages 1A away from the dicing tape 600, it is possible to batch fabricate a plurality of semiconductor packages 1A, as shown in FIG. 10.

As described above, a step of warming so that the temperature of the chip stack 3A does not fall to the room temperature is provided in the present embodiment between the step of forming the chip stack 3A and the step of sealing the chip stack 3A with the underfilling material 4. That is, in the present embodiment, the mutually opposing first bump electrodes 12a and second bump electrodes 12b of the plurality of semiconductor chips 11a to 11e are bonded by hot-press bonding. After that, the underfilling material 4 is filled into each gap between the plurality of semiconductor chips 11a to 11e. Up until the point at which the underfilling material 4 is thermally cured, the chip stack 3A is maintained at minimally a prescribed temperature. By doing this, it is possible to suppress the warping behavior of the plurality of semiconductor chips 11a to 11e constituting the chip stack 3A caused by temperature change.

According to the present embodiment, by maintain the chip stack 3A at minimally a prescribed temperature, the flowability of the underfilling material 4 when the underfilling material 4 fills the gaps between the plurality of semiconductor chips 11a to 11e constituting the chip stack 3A is improved. Therefore, the underfilling material 4 is preferably filled into these gaps and the occurrence of voids and the like are reduced.

According to the present embodiment, after curing of the underfilling material 4, the hardened underfilling material 4 suppresses the warping behavior of the semiconductor chips 11a to 11e until the temperature of the chip stack 3A reaches the room temperature. Specifically, after the underfilling material 4 is cured, by reducing the temperature of the chip stack 3A to the room temperature, contraction and the like of the underfilling material 4 occur. However, the warping behavior between the semiconductor chips 11a to 11e held by the underfilling material 4, including even differing types of chips, is the same.

Therefore, according to the present embodiment, the stress imparted to the semiconductor chips 11a to 11e is reduced, enabling a reduction in stress imparted to the bonds of the semiconductor chips 11a to 11e. It can suppress the breakage of the bonds and the occurrence of cracking and the like of the semiconductor chips 11a to 11e, thereby enabling an improvement in the connection reliability of the semiconductor package 1A, formed using existing facilities as is.

### Second Embodiment

### Semiconductor Device

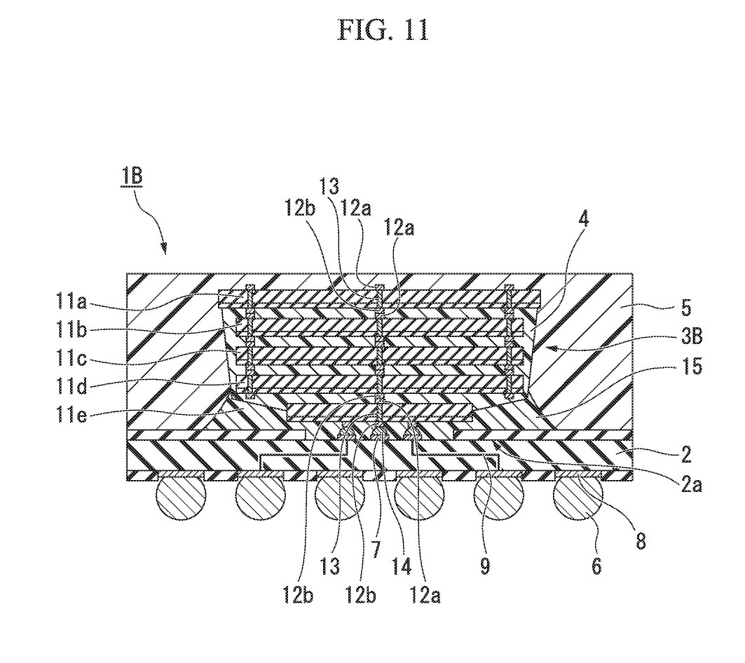

A CoC type semiconductor package 1B that is shown in FIG. 11 will be described as a second embodiment. In the following description, locations that are the same as in the semiconductor package 1A shown in FIG. 1 are assigned the same symbols in the drawings.

The semiconductor package 1B, as shown in FIG. 11, may include, but is not limited to, an interconnect substrate 2, a chip stack 3B, an underfilling material 4 (first sealing element), a molding resin (second sealing element) 5, and a plurality of solder balls (external connection terminals) 6. The chip stack 3B is mounted to one surface (upper surface) of the interconnect substrate 2. The underfilling material 4 covers the chip stack 3B. The molding resin 5 covers the underfilling material 4. The plurality of solder balls 6 are disposed on the other surface (lower surface) of the interconnect substrate 2. The semiconductor package 1B has a package structure know as a BGA.

The interconnect substrate 2 is made of a printed circuit board having a rectangular plan-view shape. This printed circuit board may be, but is not limited to, an insulating substrate on which a conductive pattern or the like made of a conductive material such as copper is formed. The conductive pattern is covered with an insulating material such as solder resist. The insulating substrate may include, but is not limited to, fiberglass epoxy resin.

In this example, an interconnect substrate 2 having a thickness of approximately 0.2 mm is used.

In the center part of the upper surface of the interconnect substrate 2, a mounting area 2a is provided onto which a chip stack 3B is mounted. A plurality of pad electrodes (third connection electrodes) 7 are arranged in the mounting area 2a of the interconnect substrate 2. On the other surface (lower surface) of the interconnect substrate 2 are arranged a plurality of connection lands 8. The above-noted solder balls 6 are disposed above these connection lands 8. A lead interconnect part 9 (shown schematically in FIG. 11) with vias and interconnect patterns and the like for electrical connection between the pad electrodes 7 and the connection lands 8 is provided on the interconnect substrate 2. With the exception of the parts in which the above-described pad electrodes 7 and connection lands 8 are formed, the surface of the interconnect substrate 2 is covered with an insulating film (not shown).

The chip stack 3B may include, but is not limited to, a plurality of (five, in this example) stacked semiconductor chips 11a to 11e, these being, in sequence from the side opposite the interconnect substrate 2 (the uppermost side), a plurality (four, in this example) of memory chips (first semiconductor chips) 11a to 11d and an interface chip (second semiconductor chip) 11e are formed. Each of the plurality (in this example, four) of memory chips (first semiconductor chips) 11a to 11d may include, but is not limited to, DRAM (dynamic random-access memory) circuits and the like are formed. The interface chip (second semiconductor chip) 11e may include, but is not limited to, interface circuits for interfacing between each of the memory chips 11a to 11d and the interconnect substrate 2. In this example, semiconductor chips 11a to 11e having a thickness of approximately 50 μm are used.

The plurality of memory chips 11a to 11d have a rectangular shape when seen in plan view. The plurality of memory chips 11a to 11d have a shape that is smaller than that of the interconnect substrate 2. The first-layer memory chip 11a has a shape that is larger than that of the other memory chips 11b to 11d. Each of the memory chips 11a to 11d may include, but is not limited to, a plurality of first bump electrodes (first connection terminals) 12a on one surface side thereof. Each of the memory chips 11a to 11d may include, but is not limited to, a plurality of second bump electrodes (second connection terminals) 12b on the other surface side thereof. Each of the memory chips 11a to 11d may include, but is not limited to, a plurality of through electrodes (TSVs) 13 making connections between these first bump electrodes 12a and the second bump electrodes 12b. The plurality of memory chips 11a to 11d are stacked, with the one surface and other surfaces thereof brought into opposition, the first bump electrodes 12a and the second bump electrodes 12b therebetween being bonded.

The interface chip 11e has a rectangular shape viewed in plan view. The interface chip 11e has a shape that is smaller than the above-noted memory chips 11a to 11d. The interface chip 11e may include, but is not limited to, a plurality of first bump electrodes (first connection terminals) 12a on one surface side thereof. The interface chip 11e may include, but is not limited to, a plurality of second bump electrodes (second connection terminals) 12b on the other surface side thereof. The interface chip 11e may include, but is not limited to, a plurality of through electrodes (TSVs) 13 making connections between these first bump electrodes 12a and the second bump electrodes 12b. The interface chip 11e is stacked with the one surface thereof and the other surface of the memory chip 11d brought into opposition, the first bump electrodes 12a and the second bump electrodes 12b therebetween being bonded.

With the interface chip 11e of the chip stack 3B positioned at the uppermost layer facing downward and the other surface of the interface chip 11e being brought into opposition with one surface (mounting area 2a) of the interconnect substrate 2, the second bump electrodes 12b and the pad electrodes 7 therebetween are bonded, via wire bumps (bonding members) 14. Additionally the chip stack 3B is adhered and held to the mounting area 2a of the interconnect substrate 2, via an insulating adhesive member 15 that fills between the one surface of the interconnect substrate 2 and the other surface of the interface chip 11e.

The above-noted interface chip 11e may include, but is not limited to, on both sides of the through electrodes 13 in the center part thereof, a plurality of second bump electrodes 12b in an alternately spaced arrangement. The plurality of second bump electrodes 12b are aligned with the pitch of the pad electrodes 7 of the above-noted interconnect substrate 2, a plurality of second bump electrodes 12b in an alternately spaced arrangement. Between the second bump electrodes 12b on both sides of the through electrodes 13 and the through electrodes 13 is provided an interconnect pattern (not shown) for the purpose of reconnection, thereby adjusting the pitch with the pad electrodes 7 of the interconnect substrate 2.

In the plurality of memory chips 11a to 11d, with respect to the plurality of through electrodes 13 arranged in the center part thereof, a plurality of through electrodes 13 on both sides interposing the center part constitute dummy electrodes so as to reinforce connection.

The underfilling material 4, as a first sealing element is thermally cured, so as to seal the chip stack 3B, after filling in each of the gaps between the plurality of semiconductor chips 11a to 11e constituting the chip stack 3B.

The molding resin 5, as a second sealing element, provides overall sealing of the entire one surface side of the interconnect substrate 2, in a condition in that covers the entire chip stack 3B that was sealed by the underfilling material 4.

### (Method for Manufacturing a Semiconductor Device)

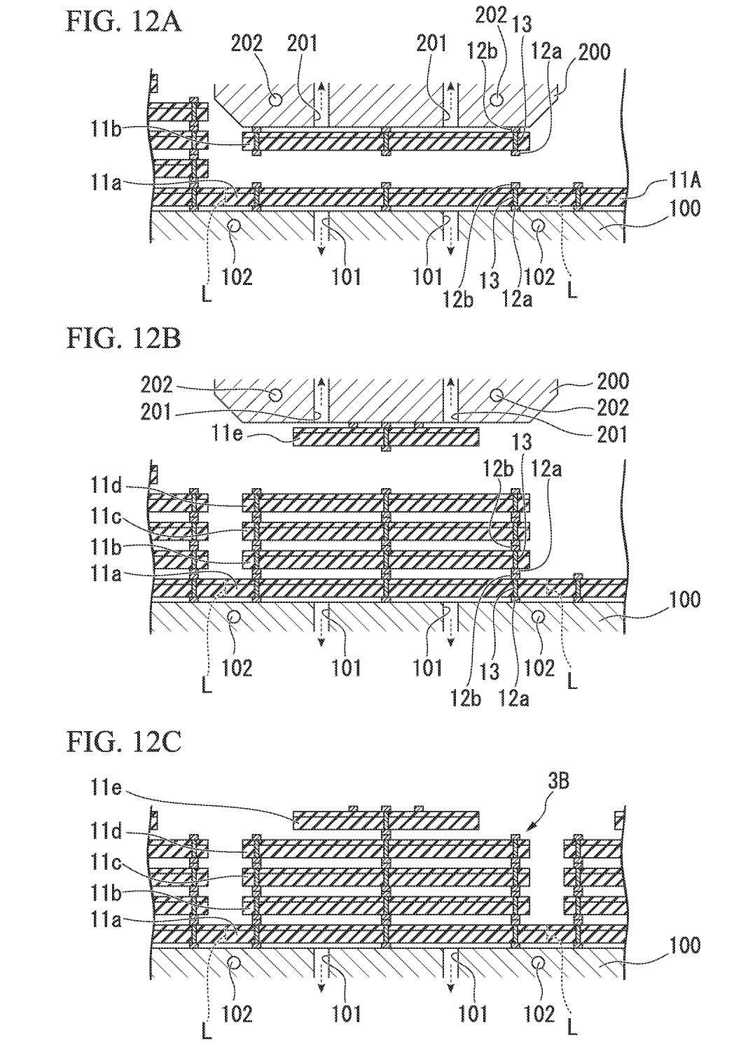

When the above-described semiconductor package 1B is formed, first, as shown in FIG. 12A to 12C, the chip stack 3B that is the stacking of the above-noted plurality of memory chips 11a to 11e is formed.

As shown in FIG. 12A, a semiconductor substrate 11A with an arrangement of a plurality of parts that become the first-layer memory chips 11a is prepared. This semiconductor substrate 11A is made of a silicon substrate having a plurality of parts that become the first-layer memory chips 11a arranged in matrix fashion. The semiconductor substrate 11A can be cut away into individual memory chips 11a by finally dicing the part that will become the first-layer memory chips 11a along a dicing line (dividing line) L.

The second-layer to fourth-layer memory chips 11b to 11d and the interface chip 11e are stack-mounted (flip-ship mounted) on the surface of the semiconductor substrate 11A for each of the part that will become the first-layer memory chip 11a.

For example, the semiconductor substrate 11A is placed onto the vacuum chuck stage 100, with the surface thereof (one surface) having formed thereon the above-noted first bump electrodes 12a facing downward. By doing this, the semiconductor substrate 11A is vacuum chucked by the plurality of vacuum holes 101 provided on the vacuum chucking stage 100, thereby holding it stably onto the vacuum chuck stage 100.

From this condition, using the bonding tool 200 the second-layer memory chip 1b is stack-mounted (flip-chip mounted) onto the part that becomes the first-layer memory chip 11a on the semiconductor substrate 11A.

In this flip-chip mounting, while the vacuum holes 201 provided in the bonding tool 200 vacuum chuck the second-layer memory chip 11b, the bonding tool 200 holds the memory chip 11b with the surface (one surface) on which the first bump electrodes 12a are formed facing downward.

The bonding tool 200, as shown in FIG. 12B, brings one surface of the second-layer memory chip 11b and the other surface of the part of the semiconductor substrate 11A, which becomes the above-noted first-layer memory chip 11a, beneath it into opposition. The bonding tool 200 places the second-layer memory chip 11b on to the part of the semiconductor substrate 11A, which becomes the first-layer memory chip 11a, with the positions of the first bump electrodes 12a and the second bump electrodes 12b therebetween aligned.

In this condition, the bonding tool 200 applies a load and ultrasonic waves as it heats at a prescribed temperature (for example, from a room temperature to approximately 150° C.) so as to bond (flip-ship bond) the first bump electrodes 12a and the second bump electrodes 12b by thermosonic bonding.

By doing this, an electrical connection (flip-chip connection) is made between the first bump electrodes 12a and the second bump electrodes 12b. The second-layer memory chip 11b is flip-chip mounted on the part that will become the first-layer memory chips 11a.

From this condition, using the same method as in the case of the flip-chip mounting the second-layer memory chip 11b as described above, the third-layer memory chip 11c is mounted to the second-layer memory chip 11b, the fourth-layer memory chip 11d is mounted to the third-layer memory chip 11c, and the fifth-layer interface chip 11e is mounted to the fourth-layer memory chip 11d by successive flip-chip mounting. The operation that uses this type of bonding tool 200 is repeated for each part that becomes a first-layer memory chip 11a of the semiconductor substrate 10A.

By doing this, as shown in FIG. 12C, the pre-separation chip stack 3B that is the stacking of the above-noted second-layer to fourth-layer memory chips 11b to 11d and the interface chip 11e onto the surface of the semiconductor substrate 11A for each part to become the first-layer memory chip 11a is obtained.

According to the present embodiment, the semiconductor substrate 11A can be stably vacuum chucked onto the vacuum chucking stage 100, when the plurality of memory chips 11b to 11d and the interface chip 11e are flip-chip mounted onto the semiconductor substrate 11A using the bonding tool 200. Therefore, heat bonding by the conventional high temperature (for example, approximately 300° C.) is not required. It is possible to bond by thermosonic bonding, for example, at a room temperature to approximately 150° C.

By doing this, it is possible to form a highly reliable semiconductor package 1B by virtue of the reduced influence of heat on the above-described plurality of memory chips 11a to 11d and the interface chip 11e. It is also possible to achieve an efficient assembling process by virtue of handling the semiconductor substrate 11A as is when the semiconductor substrate 11A is diced to divide it into the individual chip stacks 3B as described later.

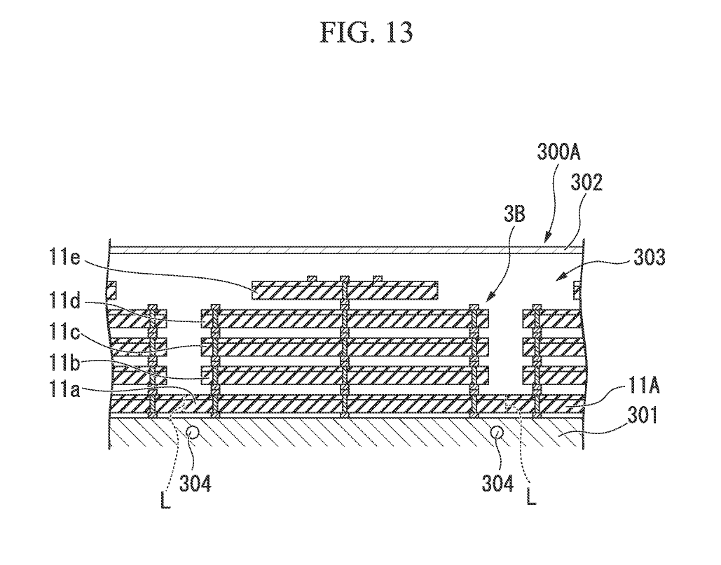

In the condition as shown in FIG. 13, the pre-separation chip stack 3B is warmed in the condition of being housed in a heat-insulating tray 300A, so that the temperature thereof does not drop to a room temperature, and is transported to the next process step. In this case, it is possible to suppress the temperature-change-induced warping behavior of the plurality of the semiconductor chips (the above-noted second-layer to fourth-layer memory chips 11b to 11d and the interface chip 11e) that are stacked for each part that will become the first-layer memory chip 11a of the semiconductor substrate 11A, in the pre-separation chip stack 3B that is in the heated condition.

The heat-insulating tray 300A has basically the same structure as the heat-insulating tray 300 shown in the above-noted FIG. 3, except for being constituted by a tray body 301 and a tray body 302 that have a sufficient housing space 303 for housing the pre-separation chip stack 3B shown in the above-noted FIG. 12C.

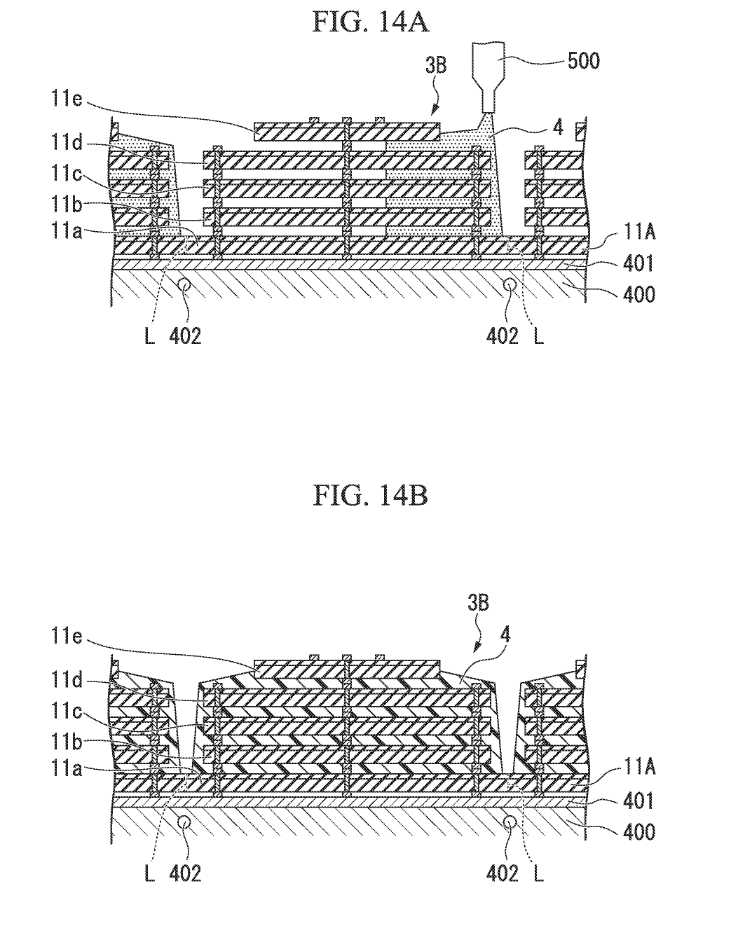

As shown in FIG. 14A and FIG. 14B, the above-noted underfilling material 4 is filled into each of the gaps of the pre-separation chip stack 3B, which has been warmed to a prescribed temperature (for example, approximately 80 to 100° C.), thereby sealing the pre-separation chip stack 3B.

For example, the pre-separation chip stack 3B is placed onto a coating stage 400. A coating sheet 401 is attached on a surface on the coating stage 400. The coating sheet 401 is made from a material having poor wetting with the underfilling material 4, such as a fluorine-based sheet or a sheet to which a silicone-based adhesive is applied. The coating stage 400 is provided with a heater (heating means) 402 for the purpose of heating the coating stage 400. The heater 402 can heat the coating stage 400 by causing a heated working fluid to flow through a tube path provided within the coating stage 400.

From this condition, using a dispenser 500 that supplies the liquefied underfilling material 4, the underfilling material 4 is coated from the vicinity of an edge part at a position that is along one side of the pre-separation chip stack 3B in the direction of each of the gaps in the chip stack 3B. When this is done, the underfilling material 4 is filled into each of the gaps in the chip stack 3B by capillary action as it seeps into the gaps.

When this is done, because the underfilling material 4 is filled into the chip stack 3B that is in a warmed condition, the flowability of the underfilling material 4 is improved. Also, it is possible to achieve good filling of the underfilling material 4 into each gap in the chip stack 3B, and to reduce the occurrence of voids and the like.

From this condition, as shown in FIG. 14B, by heating (curing) the underfilling material 4 at, for example, approximately 125° C., the underfilling material 4 hardens. By doing this, a pre-separation chip stack 3B that is sealed by the underfilling material 4 is formed. The operation that uses this type of the dispenser 500 is repeated for each above-noted pre-separation chip stack 3B.

In the chip stack 3B that is sealed by the underfilling material 4, when lowering the temperature to a room temperature after curing the underfilling material 4, it is possible for the cured underfilling material 4 to suppress the warping behavior of the plurality of semiconductor chips (the above-noted second-layer to fourth-layer memory chips 11b to 11d and interface chip 11e) that are stacked for each part that will become the first-layer memory chip 11a of the semiconductor substrate 11A.

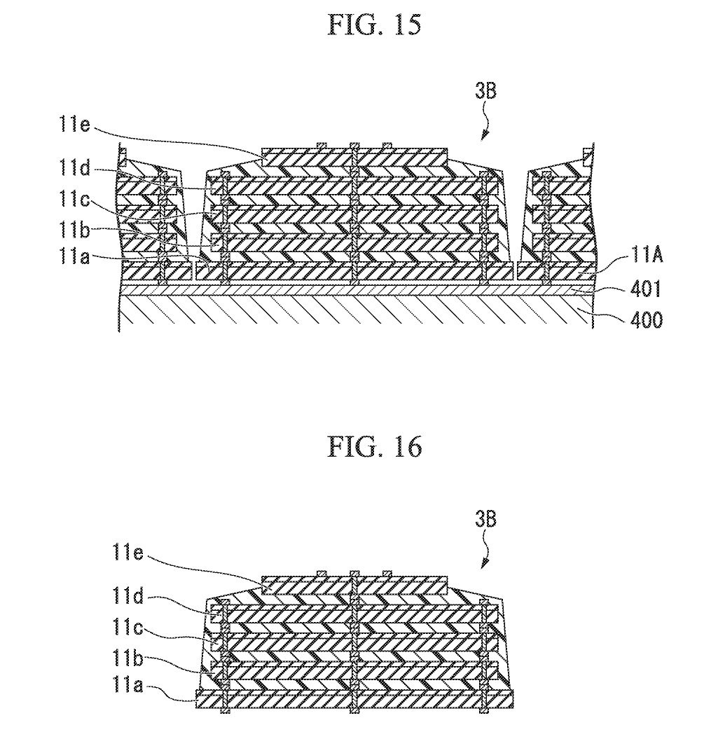

As shown in FIG. 15, a dicing blade (not shown) is used to dice the semiconductor substrate 11A into the parts to become the first-layer memory chips 11a, thereby separating it into the individual chip stacks 3B.

As shown in FIG. 16, the separated chip stack 3B is peeled away from the coating sheet 401. By doing this, it is possible to batch fabricate the chip stacks 3B sealed by the underfilling material 4. The chip stacks 3B sealed by the underfilling material 4 are then housed in a housing tray (not shown), and is transported to the next process.

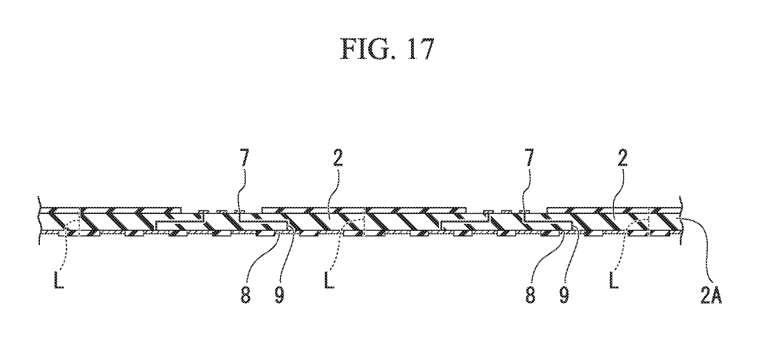

As shown in FIG. 17A, a wiring board 2A with an arrangement of a plurality of parts that become the interconnect substrates 2 is prepared. This interconnect wiring board 2A may be, but is not limited to, a fiberglass epoxy board, having a plurality of parts that become the interconnect substrates 2 arranged in matrix fashion. By finally dicing the parts that will become the interconnect substrates 2 along the dicing line L, the wiring board 2A can be cut away into individual interconnect substrates 2.

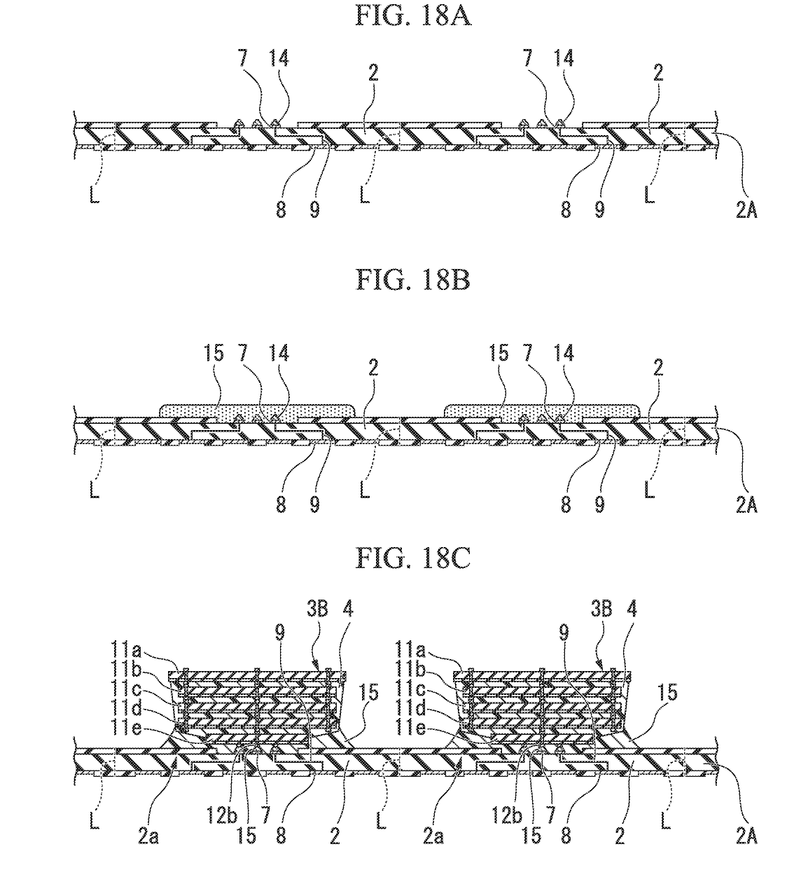

As shown in FIG. 18A to 18C, the chip stacks 3B that are sealed by the underfilling material 4 are mounted on one surface of this interconnect wiring board 2A for each of the parts that will become the interconnect substrates 2.

For example, as shown in FIG. 18A, a wire bump 14 is disposed over each pad electrode 7 in the parts that become the interconnect substrates 2. The wire bumps 14 are formed, for example, by using a wire bonding apparatus as follows. Wires made of gold, copper, or the like having melted balls at the ends thereof are bonded onto the pad electrodes 7 using heat, pressure and ultrasonic energy. Then, the rear ends of the wires are pulled to cut them.

From this condition, as shown in FIG. 18B, a dispenser (not shown) that supplies a liquefied adhesive member 15 known as NCP (non-conductive paste) is used to apply the adhesive member 15 to each of the mounting areas 2a of parts that become the interconnect substrates 2 of the wiring board 2A.

From this condition, as shown in FIG. 18B, a bonding tool (not shown) is used to flip-chip mount the chip stacks 3B to the mounting areas 2a of the parts that become the interconnect substrates 2 of the wiring board 2A.

In this flip-chip mounting, the chip stack 3B is vacuum chucked by the vacuum suction holes of the bonding tool, as the chip stack 3B is held by the bonding tool, with the interface chip 11e facing downward.

The bonding tool brings one surface of the interface chip 11e into opposition with the mounting area 2a of the part that becomes the interconnect substrate 2 and, with the positions of the first bump electrodes 12a and the pad electrodes 7 therebetween aligned. In this condition, the bonding tool places the chip stack 3B, which is sealed by the underfilling material 4, onto the mounting area 2a of the part that will become the interconnect substrate 2. By the bonding tool heating to a high temperature (for example, approximately 300° C.) while applying a load, the second bump electrodes 12b and the pad electrodes 7 are thermally bonded (flip-chip bonded) via the wire bumps 14. When this bonding is done, ultrasonic waves may be applied in addition to a load.

By doing this, an electrical connection (flip-chip connection) is made between the second bump electrodes 12b and the pad electrodes 7 via the wire bumps 14. The chip stacks 3B that are sealed by the underfilling material 4 are flip-chip mounted to the mounting area 2a of the parts that becomes the interconnect substrates 2 of the wiring board 2A.

The adhesive member 15 is cured in the condition in which it seeps out from between the one surface of the wiring board 2A and the one surface of the interface chip 11e. By doing this, the chip stack 3B that is sealed by the underfilling material 4 is adhered and held, via the adhesive member 15, to the mounting area 2a of the part that becomes the interconnect substrate 2 of the wiring board 2A. The operation that uses this type of bonding tool is repeated for each part that becomes an interconnect substrate 2 of the wiring board 2A.

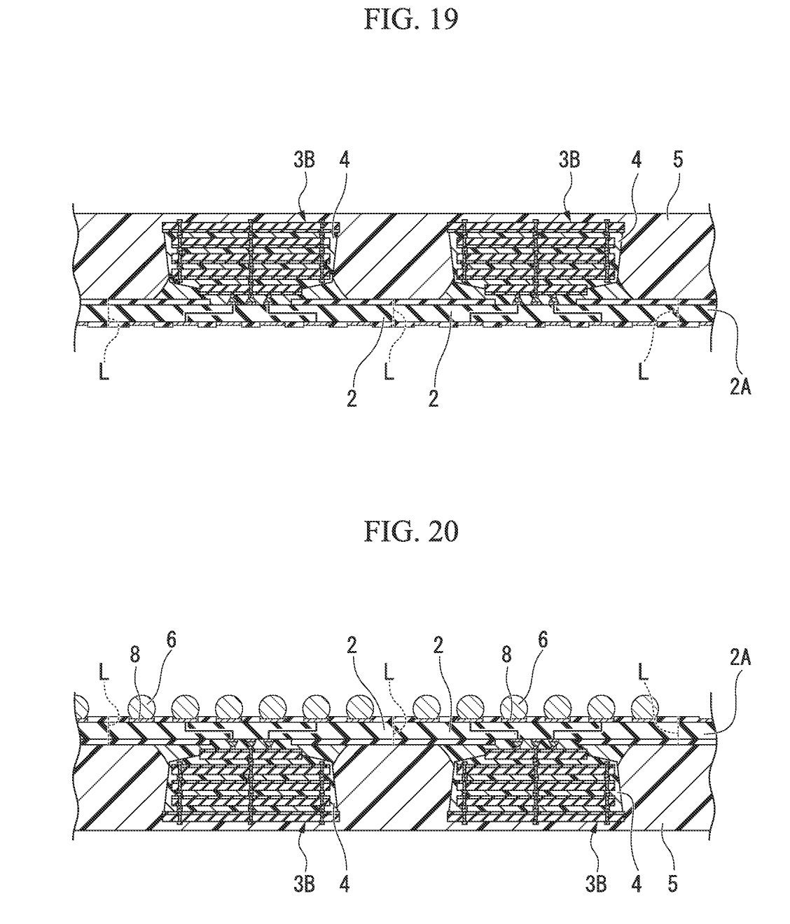

As shown in FIG. 19, one side of the wiring board 2A is sealed with the molding resin 5, so as to cover the chip stacks 3B that are sealed by the underfilling material 4. For example, a transfer molding apparatus (not shown) is used. This transfer molding apparatus has a pair of molds, constituted by a lower mold (fixed mold) and an upper mold (moving mold). The lower mold holds the other surface side of the wiring board 2A. The upper mold forms a cavity space into which the molding resin 5 is filled. The upper mold is in opposition to the one surface side of the wiring board 2A. The upper mold moves relatively to join or to separate freely with respect to the lower mold.

Then, the wiring board 2A onto which the chip stack 3B that is sealed with the underfilling material 4 is mounted is set into the transfer molding apparatus mold. that has been heated to melting is injected into the cavity space within the mold. The molding resin 5 may be, but is not limited to, a thermally cured resin such as an epoxy resin.

In this condition, by heating (curing) the molding resin 5 at a prescribed temperature (for example, approximately 180° C.) the molding resin 5 hardens. By additionally baking at a prescribed temperature, the molding resin 5 is completely hardened. By doing this, the one surface side of the wiring board 2A is completely sealed by the molding resin 5.

As shown in FIG. 20, the solder balls 6 are placed onto the connection lands 8 that are provided on the parts that become the interconnect substrates 2 of the wiring board 2A. For example, a mounting tool (not shown) of a ball mounter in which a plurality of vacuum suction holes are formed is used to vacuum chuck a plurality of solder balls 6. The mounting tool transfers and forms flux onto the plurality of solder balls 6, after which the solder balls 6 are placed on the connection lands 8 of each part that will become the interconnect substrates 2 of the wiring board 2A. Then, after placing solder balls 6 on all of the parts that will become the interconnect substrates 2 of the wiring board 2A, reflowing is performed to the wiring board 2A. By doing this, the solder balls 6 are disposed over the connection lands 8 of the parts that will become the interconnect substrates 2 of the wiring board 2A.

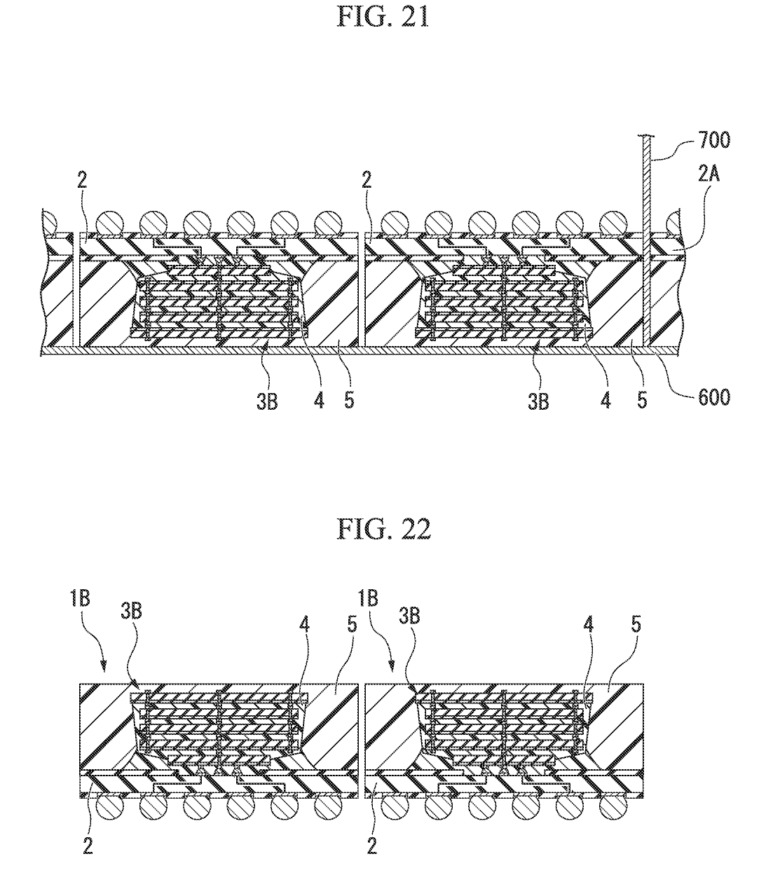

As shown in FIG. 21, by dicing the wiring board 2A into the parts that will become the interconnect substrates 2, separation is done into the individual semiconductor packages 1B. For example, a dicing tape 600 is attached to the molding resin 5 side of the wiring board 2A. Then, a dicing blade 700 is used to dice the wiring board 2A along the dicing line L, from the side opposite the side with the dicing tape 600. By doing this, separation is done into the individual semiconductor packages 1B. Then, by peeling these semiconductor packages 1B away from the dicing tape 600, it is possible to batch fabricate a plurality of semiconductor packages 1B, as shown in FIG. 22.

As described above, a step of warming so that the temperature of the chip stack 3B does not fall to the room temperature is provided in the present embodiment between the step of fabricating the chip stack 3B and the step of sealing the chip stack 3B with the underfilling material 4. That is, in the present embodiment, after bonding by hot-press bonding of the mutually opposing first bump electrodes 12a and second bump electrodes 12b of the plurality of semiconductor chips 11a to 11e are bonded by hot-press bonding (with the first-layer memory chip 11a, however, under the condition of the semiconductor substrate 11A). After that, the underfilling material 4 is filled into each gap between the plurality of semiconductor chips 11a to 11e. Up until the point at which the underfilling material 4 is thermally cured, the chip stack 3B is maintained at minimally a prescribed temperature. By doing this, it is possible to suppress the warping behavior of the plurality of semiconductor chips 11a to 11e constituting the chip stack 3B caused by temperature change.

According to the present embodiment, by maintain the chip stack 3B at minimally a prescribed temperature, the flowability of the underfilling material 4 when the underfilling material 4 fills the gaps between the plurality of semiconductor chips 11a to 11e constituting the chip stack 3B is improved. Therefore, the underfilling material 4 is preferably filled into these gaps and the occurrence of voids and the like are reduced.

According to the present embodiment, after curing of the underfilling material 4, the hardened underfilling material 4 suppresses the warping behavior of the semiconductor chips 11a to 11e until the temperature of the chip stack 3B reaches the room temperature. Specifically, after the underfilling material 4 is cured, by reducing the temperature of the chip stack 3B to the room temperature, contraction and the like of the underfilling material 4 occur. However, the warping behavior between the semiconductor chips 11a to 11e held by the underfilling material 4, including even differing types of chips, is the same.

Therefore, according to the present embodiment, the stress imparted to the semiconductor chips 11a to 11e is reduced, enabling a reduction in stress imparted to the bonds of the semiconductor chips 11a to 11e. It can suppress the breakage of the bonds and the occurrence of cracking and the like of the semiconductor chips 11a to 11e, thereby enabling a great improvement in the connection reliability of the semiconductor package 1B, formed using existing facilities as is.

It is apparent that the present invention is not limited to the above embodiments, but may be modified and changed without departing from the scope and spirit of the invention.

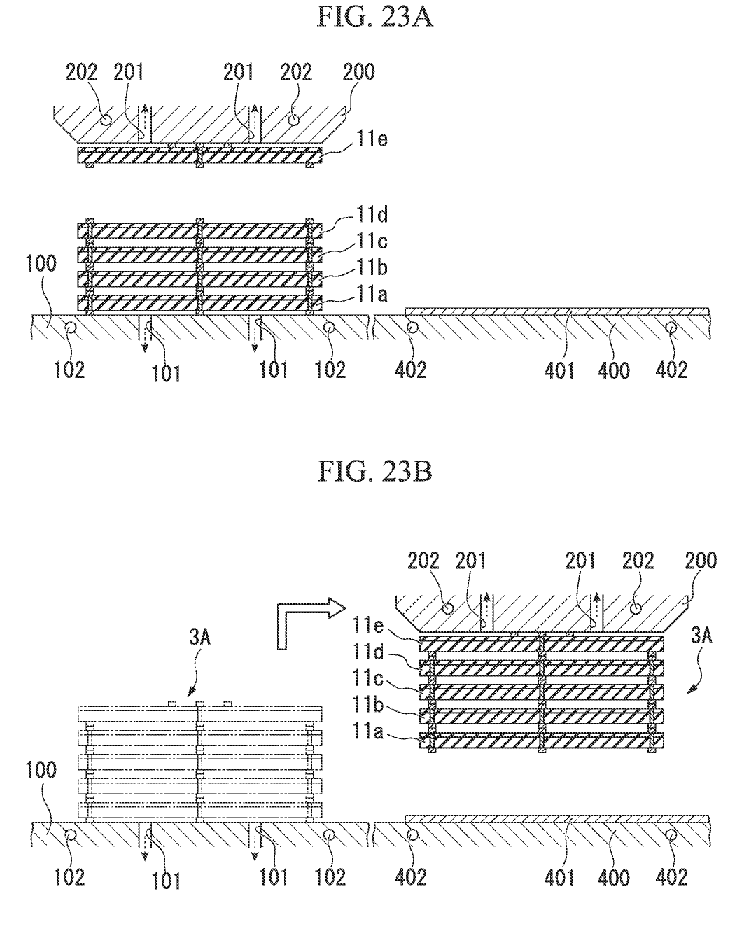

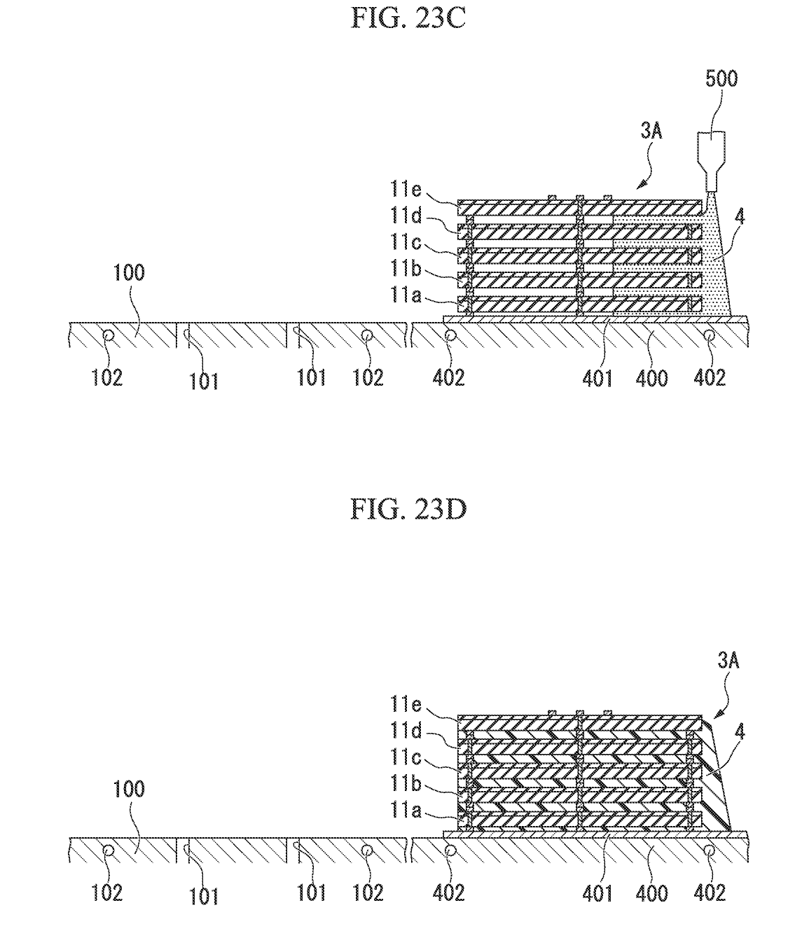

For example, as shown in FIGS. 23A and 23D, in order to improve further manufacturing efficiency, the step of forming the chip stacks 3A and the step of filling the underfilling material 4 may be integrated. Also, the underfilling material 4 may be filled after forming the chip stack 3A, which remains in the warmed condition after forming the chip stack 3A.

For example, as shown in FIG. 23A, the first-layer memory chip 11a is placed onto the vacuum chuck stage 100, in a similar manner as in the process steps shown in FIG. 2A to 2C. Then, the second-layer to fourth-layer memory chips 11b to 11d and the fifth-layer interface chip 11e are successively stack-mounted, using the bonding tool 200, forming the chip stack 3A.

As shown in FIG. 23B, the chip stack 3A on the vacuum chuck stage 100 is transported to the coating stage 400, as it is warmed using the bonding tool 200.

As shown in FIG. 23C, using the dispenser 500, the underfilling material 4 is filled into the chip stack 3A placed on the coating sheet 401 of the coating stage 400.

From this condition, as shown in FIG. 23D, by heating (curing) the underfilling material 4, the underfilling material 4 hardens. By doing this, a chip stack 3A that is sealed by the underfilling material 4 can be obtained.

Although the above-noted chip stacks 3A and 3B are constituted by combining the memory chips 11a to 11d and the interface chip 11e, it may be possible to arbitrarily change the types, sizes or the like of the chips.

Also, the above-described embodiments are not necessarily restricted to the constitution of the above described chip stacks 3A and 3B that are constituted by five layers. The number of stacked chips in the chip stacks 3A and 3B can be two or more, and may be four or less or six or more. The arrangement and number of the first bump electrodes 12a, the through electrodes 13, and the second bump electrodes 12b are also not necessarily restricted to the constitution of the above-noted chip stacks 3A and 3B, and the embodiments may be subjected to arbitrary changes.

Also, according to the above-described embodiments, after forming the chip stacks 3A and 3B stacking the plurality of the semiconductor chips 11a to 11e onto the interconnect substrate 2, the underfilling material 4 can be filled into each of the gaps of the plurality of the semiconductor chips 11a to 11e constituting the chip stacks 3A and 3B, with the chip stacks 3A and 3B warming maintained.

Also, according to the above-described embodiments, the plurality of the semiconductor chips 11a to 11e are stacked and the underfilling material 4 is filled into each of the gaps of the plurality of the semiconductor chips 11a to 11e. However, the above-described embodiments are applicable to the case where the semiconductor chips is stacked over the wiring board 2A and the underfilling material is filled into a gap between the wiring board 2A and the semiconductor chips.

Also, the above-described embodiments are applicable not only to the above-noted BGA-type semiconductor package 1, but also to other semiconductor packages, such as an LGA (land grid array) type or a CSP (chip-size package) type.

As used herein, the following directional terms “above, downward, and below” as well as any other similar directional terms refer to those directions of an apparatus equipped with the present invention. Accordingly, these terms, as utilized to describe the present invention should be interpreted relative to an apparatus equipped with the present invention.

The term “configured” is used to describe a component, section or part of a device which includes hardware and/or software that is constructed and/or programmed to carry out the desired function.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of manufacturing a semiconductor device, the method comprising:
stacking a first semiconductor chip and a second semiconductor chip to form a stacked structure;
filing a gap between the first and second semiconductor chips of the stacked structure with a filler; and
keeping a temperature of the stacked structure more than a room temperature from the stacking to the filing.

2. The method according to claim 1, wherein keeping the temperature of the stacked structure comprises:
housing the stacked structure in a heat-insulating tray.

3. The method according to claim 1, wherein keeping the temperature of the stacked structure comprises:
keeping the temperature of the stacked structure in a rage of 80° C. to 100° C.

4. The method according to claim 1, further comprising:
forming a passivation film over the first semiconductor chip and the second semiconductor chip before stacking the first semiconductor chip and the second semiconductor chip.

5. The method according to claim 1, wherein stacking the first semiconductor chip and the second semiconductor chip comprises:
heating the first semiconductor chip and the second semiconductor chip while applying a load to the first semiconductor chip and the second semiconductor chip.

6. The method according to claim 1, further comprising:
hardening the filler by heating the first semiconductor chip and the second semiconductor chip.

7. The method according to claim 1, further comprising:
stacking the stacked structure on a wiring board; and
sealing the stacked structure and the wiring board with a resin.

8. The method according to claim 1, wherein filing the gap comprises:
heating the stacked structure while the gap between the first and second semiconductor chips of the stacked structure is filled with the filler.

9. A method of manufacturing a semiconductor device, the method comprising:
electrically coupling a plurality of semiconductor chips to each other;
keeping a temperature of the plurality of semiconductor chips more than a room temperature during and after electrically coupling the plurality of semiconductor chips to each other; and
filing gaps between the plurality of semiconductor chips with a filler while heating the plurality of semiconductor chips immediately after the keeping.

10. The method according to claim 9, wherein keeping the temperature of the plurality of semiconductor chips comprises:
housing the plurality of semiconductor chips in a heat-insulating tray.

11. The method according to claim 9, wherein keeping a temperature of the plurality of semiconductor chips comprises:
keeping the temperature of the plurality of semiconductor chips in a range of 80° C. to 100° C.

12. The method according to claim 9, further comprising:
forming a passivation film over the plurality of semiconductor chips before electrically coupling the plurality of semiconductor chips.

13. The method according to claim 9, wherein electrically coupling the plurality of semiconductor chips to each other comprises:
heating the plurality of semiconductor chips while applying a load to the plurality of semiconductor chips.

14. The method according to claim 9, further comprising:
hardening the filler by heating the plurality of semiconductor chips.

15. The method according to claim 9, further comprising:
stacking the plurality of semiconductor chips on a wiring board; and
sealing the plurality of semiconductor chips and the wiring board with a resin.

16. A method of manufacturing a semiconductor device, the method comprising:
forming a stacked structure including first and second substrates stacked with one another; and
filling a gap between the first and second substrates with an underfilling material while keeping a temperature of the stacked structure higher than a room temperature from the forming to the filling.

17. The method according to claim 16, wherein each of the first and second substrates is a semiconductor chip.

18. The method according to claim 16, wherein the second substrate has a size that is different from the first substrate.

19. The method according to claim 16, wherein the keeping the temperature of the stacked structure is kept in a range of 80° C. to 100° C.

20. The method according to claim 16, further comprising:
mounting the stacked structure on a wiring board; and
forming a sealing resin on the wiring board to cover the stacked structure.
